(19) United States
(12) Patent Application Publication
(10) Pub. No.: US 2026/0321493 A1
(43) Pub. Date: Oct. 15, 2026

(54) MOUNTING STRUCTURE OF ELECTRONIC COMPONENT

(71) Applicant: Murata Manufacturing Co., Ltd., Nagaokakyo-shi (JP)

(72) Inventors: Eigo KOBAYASHI, Nagaokakyo-shi (JP); Yusuke YOKOTA, Nagaokakyo-shi (JP)

(21) Appl. No.: 19/695,209

(22) Filed: Jun. 2, 2026

Related U.S. Application Data
(63) Continuation of application No. PCT/JP2024/039231, filed on Nov. 5, 2024.

(30) Foreign Application Priority Data
Dec. 4, 2023 (JP) 2023-204846

(51) Int. Cl. H01G 2/06; H01G 4/30

(52) U.S. Cl. CPC H01G 2/065; H01G 4/30

(57) ABSTRACT

A mounting structure of an electronic component includes the electronic component including a multilayer body, and outer electrodes on end surfaces of the multilayer body and including mounting surface-side folded portions extending to a mounting-side main surface, and a mounting substrate including lands to which the outer electrodes are bonded through solder. A distance between the mounting surface-side folded portions and a distance between the lands on the mounting substrate approximate each other.

### CROSS REFERENCE TO RELATED APPLICATIONS

This application claims the benefit of priority to Japanese Patent Application No. 2023-204846 filed on Dec. 4, 2023 and is a Continuation Application of PCT Application No. PCT/JP2024/039231 filed on Nov. 5, 2024. The entire contents of each application are hereby incorporated herein by reference.

### BACKGROUND OF THE INVENTION

### 1. Field of the Invention

The present invention relates to mounting structures of electronic components.

### 2. Description of the Related Art

For example, in a mounting structure of an electronic component such as a multilayer ceramic capacitor, a distance in a length direction from an end of a folded portion, of an outer electrode of the multilayer ceramic capacitor, on a main surface side to an end of a mounting land is increased to improve crack resistance (see Japanese Unexamined Patent Application Publication No. 2014-11210).

### SUMMARY OF THE INVENTION

However, the inventors have discovered that when a stress is applied to the mounting structure, a crack is more likely to occur inside a multilayer body if the distance from the end of the folded portion on the main surface side to the end of the mounting land is longer.

Example embodiments of the present invention provide mounting structures of electronic components each with improved crack resistance.

An example embodiment of the present invention provides a mounting structure of an electronic component including an electronic component including a multilayer body including a dielectric layer and an inner electrode that are alternately stacked, a mounting-side main surface and a non-mounting-side main surface opposite to each other in a stacking direction, two side surfaces opposite to each other in a width direction intersecting with the stacking direction, and a first end surface and a second end surface opposite to each other in a length direction intersecting with the stacking direction and the width direction, a first outer electrode provided on the first end surface and including a mounting surface-side folded portion that extends to the mounting-side main surface, and a second outer electrode provided on the second end surface and including a mounting surface-side folded portion that extends to the mounting-side main surface, and a mounting substrate including a first land portion to which the first outer electrode is bonded through solder, and a second land portion to which the second outer electrode is bonded through solder, in which when a distance between the first and second outer electrodes g1 is a distance in the length direction between an end of the mounting surface-side folded portion of the first outer electrode on a second outer electrode side in the length direction and an end of the mounting surface-side folded portion of the second outer electrode on a first outer electrode side in the length direction, and a distance between the first and second lands g2 is a distance in the length direction between an end of the first land on a second land side in the length direction and an end of the second land on a first land side in the length direction, the distance g1 and the distance g2 approximate each other.

In addition, another example embodiment of the present invention provides a mounting structure of an electronic component including an electronic component including a multilayer body including a dielectric layer and an inner electrode that are alternately stacked, a mounting-side main surface and a non-mounting-side main surface opposite to each other in a stacking direction, two side surfaces opposite to each other in a width direction intersecting with the stacking direction, and a first end surface and a second end surface opposite to each other in a length direction intersecting with the stacking direction and the width direction, a first outer electrode provided on the first end surface and including a mounting surface-side folded portion that extends to the mounting-side main surface, and a second outer electrode provided on the second end surface and including a mounting surface-side folded portion that extends to the mounting-side main surface, and a mounting substrate including a first land portion to which the first outer electrode is bonded through solder, and a second land portion to which the second outer electrode is bonded through solder, in which an end of the mounting surface-side folded portion of the first outer electrode on a second outer electrode side in the length direction and an end of the first land on a second land side in the length direction are located at approximately a same position in the length direction, and an end of the mounting surface-side folded portion of the second outer electrode on a first outer electrode side in the length direction and an end of the second land on a first land side in the length direction are located at approximately a same position in the length direction.

Moreover, a further example embodiment of the present invention provides a mounting structure of an electronic component including an electronic component including a multilayer body including a dielectric layer and an inner electrode that are alternately stacked, a mounting-side main surface and a non-mounting-side main surface opposite to each other in a stacking direction, two side surfaces opposite to each other in a width direction intersecting with the stacking direction, and two end surfaces opposite to each other in a length direction intersecting with the stacking direction and the width direction, outer electrodes provided on the two end surfaces and including mounting surface-side folded portions that extend to the mounting-side main surface, and a mounting substrate including land portions to which the outer electrodes are bonded through solder, in which an angle α on an acute angle side of angles defined by a straight line drawn from an end of the mounting surface-side folded portion of one of the outer electrodes on a side of another one of the outer electrodes to an end of one of the land portions on a side of another one of the land portions and the mounting-side main surface satisfies about 31°≤α≤about 90°.

According to example embodiments of the present invention, mounting structures of electronic components with improved crack resistance are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic perspective view of a mounting structure 100 of a multilayer ceramic capacitor 1.

FIG. 2 is a sectional view taken along line II-II of FIG. 1.

FIG. 3 is a sectional view taken along line III-III of FIG. 1.

FIG. 4A schematically illustrates a sectional view of a double structure, FIG. 4B a triple structure, and FIG. 4C a quadruple structure of a multilayer body 2.

FIG. 5 is a table illustrating results of substrate bending resistance tests performed with respect to Examples 1, 2, 3, and 4 and Comparative Examples 1, 2, and 3.

FIGS. 6A to 6E illustrate portions of a region S, surrounded by a dotted line in FIG. 2, of Example 1, Example 2, Example 4, Comparative Example 1, and Comparative Example 2.

### DETAILED DESCRIPTION OF THE EXAMPLE EMBODIMENTS

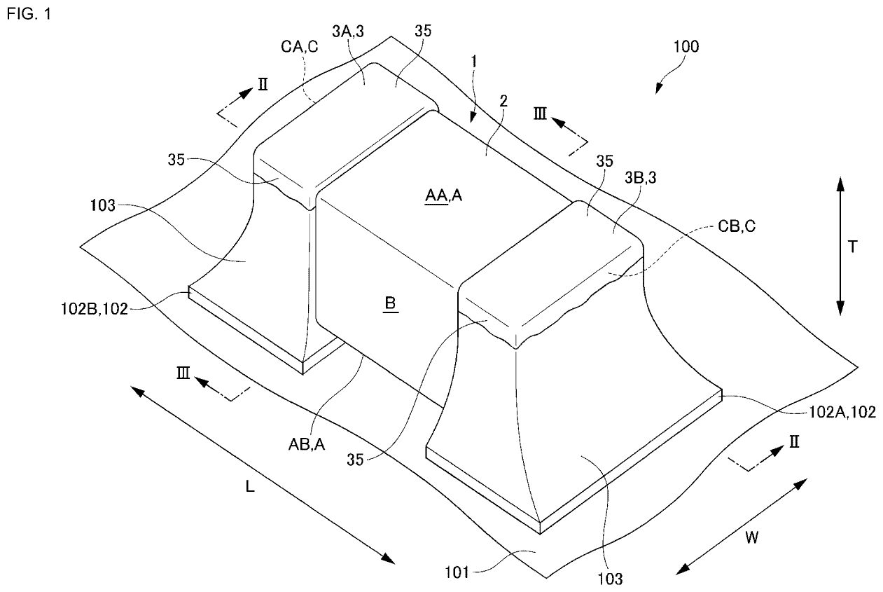

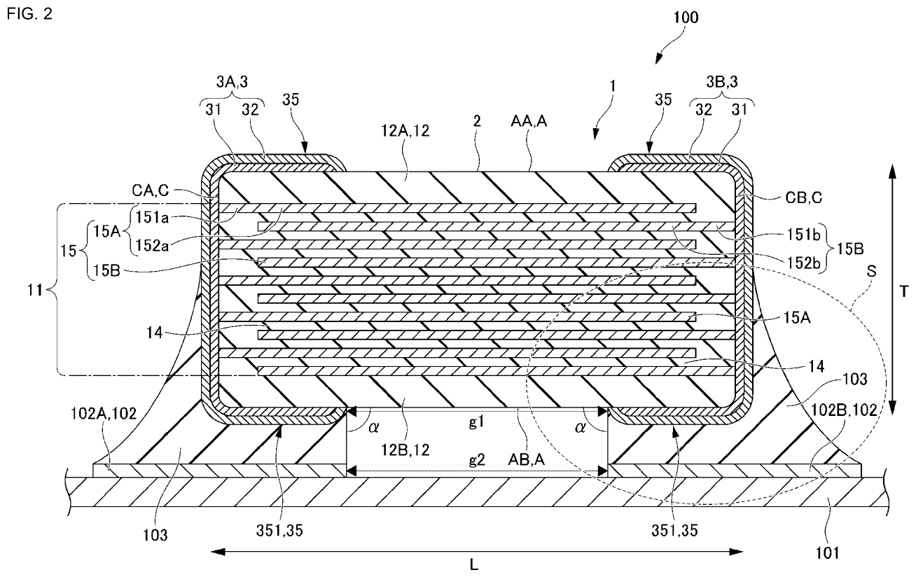

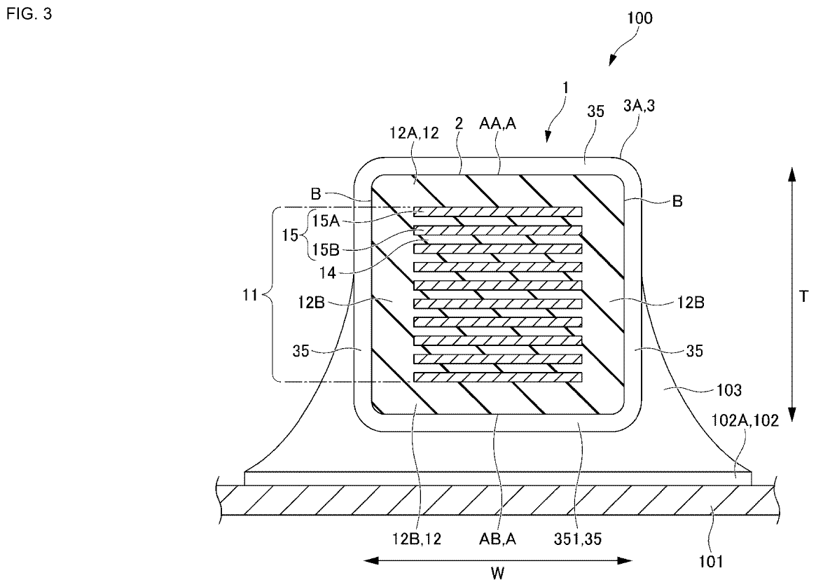

Hereinafter, mounting structures of electronic components according to example embodiments of the present invention will be described. In the description of the example embodiments, a multilayer ceramic capacitor 1 is an example of an electronic component. FIG. 1 is a schematic perspective view of the mounting structure 100 of the multilayer ceramic capacitor 1. FIG. 2 is a sectional view taken along line II-II of FIG. 1. FIG. 3 is a sectional view taken along line III-III of FIG. 1.

The mounting structure 100 includes a mounting substrate 101, a pair of land portions 102 spaced apart from each other on the mounting substrate 101, solder 103 disposed on each of the land portions 102, and the multilayer ceramic capacitor 1. The multilayer ceramic capacitor 1 is mounted on the mounting substrate 101 by the solder 103 on the land portions 102.

The multilayer ceramic capacitor 1 has a substantially rectangular parallelepiped shape and includes a multilayer body 2, and a pair of outer electrodes 3 provided at both ends of the multilayer body 2. The multilayer body 2 includes an inner layer portion 11 in which a plurality of dielectric layers 14 and a plurality of inner electrode layers 15 are stacked and an outer layer portion 12.

In the following description, as a term for a direction of the multilayer ceramic capacitor 1, a length direction L is a direction in which the pair of outer electrodes 3 is provided in the multilayer ceramic capacitor 1. A stacking direction T is a direction in which the dielectric layers 14 and the inner electrode layers 15 are stacked. A width direction W is a direction intersecting with both the length direction L and the stacking direction T. In the present example embodiment, the width direction W is orthogonal to both the length direction L and the stacking direction T.

In addition, in the following description, among six outer peripheral surfaces of the multilayer body 2 illustrated in FIG. 2, a first main surface AA and a second main surface (a mounting-side main surface AB) define a pair of outer peripheral surfaces opposite to each other in the stacking direction T, and when it is not necessary to particularly distinguish between the first main surface AA and the mounting-side main surface AB, they are collectively referred to as a main surface A. A pair of outer peripheral surfaces opposite to each other in the width direction W of the multilayer body 2 is referred to as a side surface B. A first end surface CA and a second end surface CB define a pair of outer peripheral surfaces opposite to each other in the length direction L of the multilayer body 2, and when it is not necessary to particularly distinguish between the first end surface CA and the second end surface CB, they are collectively referred to as an end surface C.

In the multilayer ceramic capacitor 1 including the multilayer body 2 and the outer electrodes 3, a dimension in the length direction L is preferably about 0.8 mm or more and about 1.2 mm or less, a dimension in the stacking direction T is preferably about 0.3 mm or more and about 0.7 mm or less, and a dimension in the width direction W is preferably about 0.3 mm or more and about 0.7 mm or less, for example.

The multilayer body 2 has a substantially rectangular parallelepiped shape and has preferably rounded corners and ridge portions. A corner is a portion where three surfaces of the multilayer body 2 intersect, and a ridge portion is a portion where two surfaces of the multilayer body 2 intersect. In addition, the main surface A, the side surface B, and the end surface C may be partially or entirely provided with, for example, irregularities.

In the multilayer body 2, a dimension in the length direction is preferably about 0.7 mm or more and about 1.2 mm or less, a dimension in the width direction W is preferably about 0.2 mm or more and about 0.7 mm or less, and a dimension in the stacking direction T is preferably about 0.2 mm or more and about 0.7 mm or less, for example.

The multilayer body 2 includes the inner layer portion 11, a main surface-side outer layer portion 12A disposed on each main surface A side of the inner layer portion 11, and a side surface-side outer layer portion 12B disposed on each side surface B side of the inner layer portion 11. When it is not necessary to particularly distinguish between the main surface-side outer layer portion 12A and the side surface-side outer layer portion 12B, they are collectively referred to as the outer layer portion 12.

In the inner layer portion 11, the plurality of dielectric layers 14 and the plurality of inner electrode layers 15 are stacked.

Each dielectric layer 14 is made of a ceramic material. As the ceramic material, for example, a dielectric ceramic material including a component such as BaTiO₃, CaTiO₃, SrTiO₃, or CaZrO₃ as a main component can be used. In addition, those obtained by adding an accessory component such as an Mn compound, an Fe compound, a Cr compound, a Co compound, or an Ni compound to these main components may be used.

A thickness of the dielectric layer 14 is preferably about 0.6 μm or more and about 1.5 μm or less, for example. The number of the dielectric layers 14 in addition to those in the outer layer portion 12 is preferably 270 or more and 490 or less, for example.

When a piezoelectric ceramic material is used for the multilayer body 2, the electronic component functions as a ceramic piezoelectric element. Specific examples of the piezoelectric ceramic material include, for example, a lead zirconate titanate (PZT)-based ceramic material.

When a semiconductor ceramic material is used for the multilayer body 2, the electronic component functions as a thermistor element. Specific examples of the semiconductor ceramic material include, for example, a spinel-based ceramic material.

When a magnetic ceramic material is used for the multilayer body 2, the electronic component functions as an inductor element. In addition, when the electronic component functions as an inductor element, each inner electrode layer 15 becomes a coil conductor. Specific examples of the magnetic ceramic material include, for example, a ferrite ceramic material.

The inner electrode layer 15 includes a plurality of first inner electrode layers 15A and a plurality of second inner electrode layers 15B. Each first inner electrode layer 15A and each second inner electrode layer 15B are alternately disposed. When it is not necessary to particularly distinguish between the first inner electrode layer 15A and the second inner electrode layer 15B, they are collectively referred to as the inner electrode layer 15. The inner electrode layer 15 can be made of an appropriate conductive material such as a metal such as Ni, Cu, Ag, Pd, or Au, or an alloy including at least one of the metals, such as an Ag-Pd alloy.

A thickness of the inner electrode layer 15 is preferably about 0.4 μm or more and about 0.6 μm or less, for example. The total number of the inner electrode layers 15 including the first inner electrode layers 15A and the second inner electrode layers 15B is preferably 270 or more and 490 or less, for example.

Each first inner electrode layer 15A includes a first facing portion 152a facing the second inner electrode layer 15B, and a first extended portion 151a extended from the first facing portion 152a toward the first end surface CA side. An end of the first extended portion 151a is exposed on the first end surface CA and is electrically coupled to a first outer electrode 3A to be described later.

Each second inner electrode layer 15B includes a second facing portion 152b facing the first inner electrode layer 15A, and a second extended portion 151b extended from the second facing portion 152b toward the second end surface CB side. An end of the second extended portion 151b is electrically coupled to a second outer electrode 3B to be described later.

In the multilayer body 2, an effective layer portion is a region where the first facing portion 152a and the second facing portion 152b overlap with each other in the stacking direction T and that is surrounded by the main surface-side outer layer portion 12A and the side surface-side outer layer portion 12B. In the effective layer portion, electric charge is accumulated in the first facing portion 152a of the first inner electrode layer 15A and the second facing portion 152b of the second inner electrode layer 15B, such that the characteristics of the capacitor are developed.

When it is not necessary to particularly distinguish between the first facing portion 152a and the second facing portion 152b, they are collectively referred to as a facing portion 152. In addition, when it is not necessary to particularly distinguish between the first extended portion 151a and the second extended portion 151b, they are collectively referred to as an extended portion 151.

A shape of the facing portion 152 is not particularly limited, but is preferably rectangular. However, the shape is not limited thereto, and may include corner portions that are rounded or obliquely shaped (tapered). It may also be inclined and tapered in either direction.

A shape of the extended portion 151 is not particularly limited, but is preferably rectangular. However, the shape is not limited thereto, and may include corner portions that are rounded or obliquely shaped (tapered). It may also be inclined and tapered in either direction.

A width of the facing portion 152 of the inner electrode layer 15 and a width of the extended portion 151 of the inner electrode layer 15 may be the same, or either one of the widths may be narrower. A structure may be provided in which the inner electrode layer 15 is provided with a floating inner electrode layer that is not extended to either one of the end surfaces, and the floating inner electrode layer divides a facing electrode portion into multiple portions.

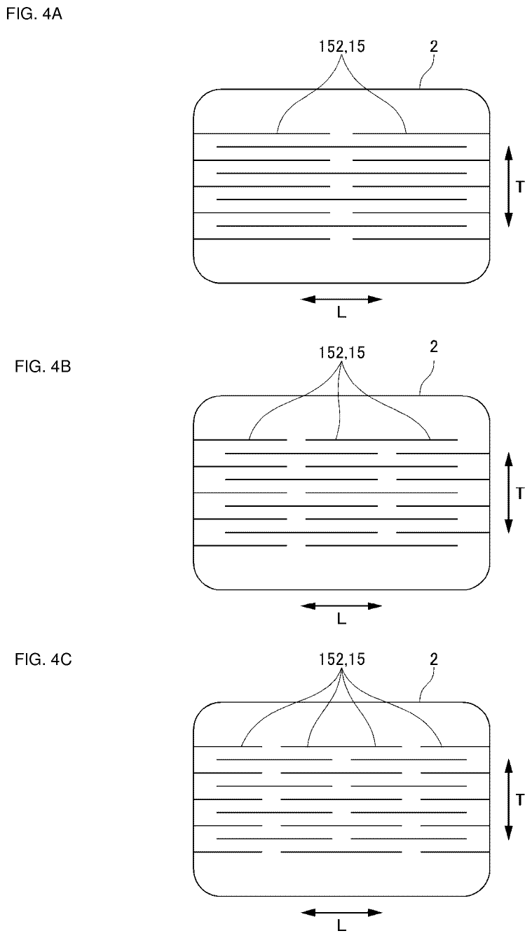

FIGS. 4A to 4C are schematic sectional views passing in the length direction L and the stacking direction T of the multilayer body 2, and illustrates a structure in which the facing portion 152 of the inner electrode layer 15 is divided into multiple portions. FIG. 4A is a double structure in which the facing portion 152 is divided into two, FIG. 4B is a triple structure in which the facing portion 152 is divided into three, and FIG. 4C is a quadruple structure in which the facing portion 152 is divided into four. Although not illustrated, quadruple or more structures may be provided.

As illustrated in FIGS. 4A to 4C, dividing the facing portion 152 of the inner electrode layer 15 into multiple portions defines multiple capacitor components among the inner electrode layers 15 facing each other, thus providing a structure in which the capacitor components are connected in series. Therefore, a voltage applied to each of the capacitor components is decreased, thus making it possible to increase a withstanding voltage of the multilayer ceramic capacitor 1.

The outer layer portion 12 is an aggregate of a plurality of the dielectric layers 14 made of the same dielectric ceramic material as the dielectric layers 14 of the inner layer portion 11.

The outer electrodes 3 include the first outer electrode 3A and the second outer electrode 3B.

The first outer electrode 3A is connected to the first inner electrode layer 15A and is disposed on the first end surface CA. The first outer electrode 3A also includes a folded portion 35 that extends to a portion of the first main surface AA and part of the mounting-side main surface AB, and to a portion of the side surface B. The folded portion 35 that extends to a portion of the mounting-side main surface AB is referred to as a mounting surface-side folded portion 351.

The second outer electrode 3B is connected to the second inner electrode layer 15B and is disposed on the second end surface CB. The second outer electrode 3B also includes the folded portion 35 that extends to a portion of the first main surface AA and part of the mounting-side main surface AB, and to a portion of the side surface B. The folded portion 35 that extends to a portion of the mounting-side main surface AB is referred to as the mounting surface-side folded portion 351, similarly to the first outer electrode 3A.

Hereinafter, when it is not necessary to particularly distinguish between the first outer electrode 3A and the second outer electrode 3B, they are collectively referred to as the outer electrode 3. The outer electrode 3 includes a base electrode layer 31 and a plating layer 32.

The base electrode layer 31 includes at least one selected from a baked layer, a conductive resin layer, a thin film layer, and the like.

The baked layer includes a glass component and a metal. The glass component includes at least one selected from B, Si, Ba, Mg, Al, Li, and the like. The metal of the baked layer includes, for example, at least one selected from Cu, Ni, Ag, Pd, an Ag-Pd alloy, Au, and the like. The baked layer may include multiple layers. The baked layer is obtained by applying a conductive paste including glass and a metal to the multilayer body 2 and baking the paste, and may be fired simultaneously with the inner electrode layers 15 and the dielectric layers 14, or may be baked after the inner electrode layers 15 are fired. When the baked layer is fired simultaneously with the inner electrode layers 15 and the dielectric layers 14, the baked layer is preferably formed by adding a dielectric material in place of the glass component.

A thickness of the baked layer in the length direction L, in the central portion in the stacking direction T and the width direction W, is preferably, for example, about 30 μm or more and about 50 μm or less. In addition, when the base electrode layer 31 (baked layer) is provided in the folded portion 35, a thickness of the folded portion 35 in the stacking direction T, in the central portion in the length direction L and the width direction W, is preferably, for example, about 3 μm or more and about 15 μm or less.

The conductive resin layer may include multiple layers. The conductive resin layer may be disposed on the baked layer so as to cover the baked layer, or may be directly disposed on the multilayer body 2. The conductive resin layer includes a thermosetting resin and a metal. Since the conductive resin layer includes a thermosetting resin, the conductive resin layer is more flexible than a conductive layer made of a plating film or a fired product of a conductive paste, for example. Therefore, even when a physical impact or an impact due to a thermal cycle is applied to a ceramic electronic component, the conductive resin layer functions as a buffer layer, thus making it possible to prevent the ceramic electronic component from being cracked.

As the metal included in the conductive resin layer, Ag, Cu, Ni, Sn, Bi, or an alloy including them can be used. In addition, a metal powder that includes a surface coated with Ag can also be used in the conductive resin layer. In the case of using a metal powder that includes a surface coated with Ag, Cu, Ni, Sn, Bi, or an alloy powder thereof is preferably used as the metal powder. An Ag conductive metal powder is used as a conductive metal because Ag has the lowest specific resistance among metals and is thus suitable for electrode materials, and because Ag is a noble metal and is not oxidized, and thus has high weather resistance. In addition, the use of an Ag conductive metal powder makes the base metal inexpensive while maintaining the above-described properties of Ag.

As the metal included in the conductive resin layer, Cu or Ni subjected to an antioxidant treatment can also be used. As the metal included in the conductive resin layer, a metal powder that includes a surface coated with Sn, Ni, or Cu can also be used. In the case of using a metal powder that includes a surface coated with Sn, Ni, or Cu, Ag, Cu, Ni, Sn, Bi, or an alloy powder thereof is preferably used as a metal powder.

The metal included in the conductive resin layer is preferably included in an amount of about 35 vol % or more and about 75 vol % or less with respect to the total volume of the conductive resin layer, for example.

A shape of the metal included in the conductive resin layer is not particularly limited. A conductive filler may be spherical, flat, or the like. An average particle size of the metal included in the conductive resin layer is not particularly limited. An average particle size of a conductive filler may be, for example, about 0.3 μm to about 10 μm. The metal included in the conductive resin layer is mainly responsible for the conductivity of the conductive resin layer. Specifically, conductive fillers are brought into contact with each other, thus defining a conductive path within the conductive resin layer. The metal included in the conductive resin layer may have a spherical shape, a flat shape, or other suitable shape, but a mixture of a spherical metal powder and a flat metal powder is preferably used.

As the resin of the conductive resin layer, any one of various known thermosetting resins can be used, such as an epoxy resin, a phenoxy resin, a phenol resin, a urethane resin, a silicone resin, and a polyimide resin. An epoxy resin, which is excellent in heat resistance, moisture resistance, and adhesion, for example, is a particularly suitable resin.

The resin included in the conductive resin layer is preferably included in an amount of about 25 vol % or more and about 65 vol % or less with respect to the total volume of the conductive resin layer, for example.

In addition, the conductive resin layer preferably includes therein a curing agent together with the thermosetting resin. When an epoxy resin is used as a base resin, any of various known compounds such as a phenol-based compound, an amine-based compound, an acid anhydride-based compound, an imidazole-based compound, an active-ester-based compound, and an amide-imide-based compound can be used as the curing agent for the epoxy resin.

A thickness of the conductive resin layer in the length direction L, located on the end surface C, located in the central portion in the stacking direction T and the width direction W, is preferably, for example, about 30 μm or more and about 50 μm or less. In addition, a thickness, which is a length of the conductive resin layer in the stacking direction T, located in the folded portion 35, in the central portion in the length direction L and the width direction W of the conductive resin layer, is preferably, for example, about 3 μm or more and about 15 μm or less.

The thin film layer is formed by a thin film formation method such as sputtering or vapor deposition and is a layer having a thickness of about 1 μm or less in which metal particles are deposited, for example.

The plating layer 32 is disposed so as to cover the base electrode layer 31. The plating layer 32 includes, for example, at least one selected from Cu, Ni, Sn, Ag, Pd, an Ag-Pd alloy, Au, and the like. The plating layer 32 may include multiple layers. The plating layer 32 preferably has a two-layer structure including an Ni plating layer and an Sn plating layer. The Ni plating layer can prevent corrosion of the base electrode layer 31 by the solder 103 when the ceramic electronic component is mounted. The Sn plating layer improves the wettability of the solder 103 when the ceramic electronic component is mounted, thus facilitating the mounting of the ceramic electronic component. A thickness of one plating layer 32 is preferably about 1 μm or more and about 10 μm or less, for example.

The outer electrode 3 may include only the plating layer 32, without the base electrode layer 31 provided. That is, the multilayer ceramic capacitor 1 may have a structure including the plating layer 32 electrically coupled to the inner electrode layer 15. In such a case, the plating layer 32 may be formed after a catalyst is provided on a surface of the multilayer body 2 as a pretreatment. In this case, the plating layer 32 preferably includes a lower layer plating electrode formed on a surface of the multilayer body 2 and an upper layer plating electrode formed on a surface of the lower layer plating electrode. Each of the upper layer plating electrode and the lower layer plating electrode preferably includes at least one metal selected from, for example, Cu, Ni, Sn, Pb, Au, Ag, Pd, Bi, and Zn, or an alloy including any of these metals. The lower layer plating electrode is preferably made of, for example, Ni, which is able to function as a barrier against solder, and the upper layer plating electrode is preferably made of, for example, Sn or Au, which has good solder wettability.

For example, when the first inner electrode layer 15A and the second inner electrode layer 15B are made of Ni, the lower layer plating electrode is preferably made of Cu, which has good bondability to Ni. The upper layer plating electrode need only be formed where necessary, and each of the first outer electrode 3A and the second outer electrode 3B may include only the lower layer plating electrode.

In the plating layer 32, the upper layer plating electrode may be provided as an outermost plating layer, or another plating layer may be additionally provided on a surface of the upper layer plating electrode. A thickness of one plating layer 32, which is disposed without the base electrode layer 31 provided, is preferably about 1 μm or more and about 15 μm or less, for example. The plating layer 32 is preferably free from glass. A ratio of a metal per unit volume of the plating layer 32 is preferably about 99 vol % or more, for example.

The mounting structure 100 of the present example embodiment includes the above-described multilayer ceramic capacitor 1, the mounting substrate 101, the pair of land portions 102 spaced apart from each other on the mounting substrate 101, and the solder 103 disposed on each of the land portions 102.

The land portions 102 include a first land portion 102A bonded to the first outer electrode 3A and a second land portion 102B bonded to the second outer electrode 3B. When it is not necessary to particularly distinguish between the first land portion 102A and the second land portion 102B, they are collectively referred to as the land portion 102.

A distance between outer electrodes g1 is a distance between a end of the mounting surface-side folded portion 351, of the first outer electrode 3A, on the second outer electrode 3B side in the length direction L and an end of the mounting surface-side folded portion 351, of the second outer electrode 3B, on the first outer electrode 3A side in the length direction L.

A distance between lands g2 is a distance in the length direction L between an end of the first land portion 102A on the second land portion 102B side in the length direction L and an end of the second land portion 102B on the first land portion 102A side in the length direction L.

In the present example embodiment, the distance between outer electrodes g1 and the distance between lands g2 approximate each other. For example, the distance between outer electrodes g1 and the distance between lands g2 approximating each other means that about −0.44≤(g1-g2)/g2≤about 0.72 is satisfied. For example, when g2=about 0.5 mm, the distance between outer electrodes g1 and the distance between lands g2 approximating each other means that about −22μm≤g1-g2≤about 36 μm is satisfied.

In other words, in the present example embodiment, as illustrated in FIG. 2, the end of the mounting surface-side folded portion 351, of the first outer electrode 3A, on the second outer electrode 3B side in the length direction L and the end of the first land portion 102A on the second land portion 102B side in the length direction L are located at approximately the same position in the length direction L. In addition, the end of the mounting surface-side folded portion 351, of the second outer electrode 3B, on the first outer electrode 3A side in the length direction L and the end of the second land portion 102B on the first land portion 102A side in the length direction L are located at approximately the same position in the length direction L.

Furthermore, in other words, in the present example embodiment, an angle α on an acute angle side defined by a straight line drawn from an end, of the mounting surface-side folded portion 351 of one of the outer electrodes 3, on a side of another one of the outer electrodes 3 to an end of one of the land portions 102, on a side of another one of the land portions 102, and the mounting-side main surface AB satisfies about 31°≤α≤about 90°, and is more preferably about 90°, for example.

First, a non-limiting example of a method of manufacturing the multilayer ceramic capacitor 1 is described. Dielectric sheets and a conductive paste for inner electrode layers are prepared. The dielectric sheets and the conductive paste for inner electrode layers include binders and solvents, which may be any of known binders or solvents.

The dielectric sheets are printed with the conductive paste for inner electrode layers in a predetermined pattern by, for example, screen printing or gravure printing, to form inner electrode layer patterns.

A predetermined number of dielectric sheets for outer layers with no inner electrode layer pattern printed are stacked. On these sheets, dielectric sheets with the inner electrode layer patterns printed thereon are stacked one after another. Further, a predetermined number of dielectric sheets for outer layers are stacked, such that a multilayer sheet is produced.

The multilayer sheet is then pressed in the stacking direction T by, for example, isostatic press, thus producing a multilayer block. Then, the multilayer block is cut.

A multilayer body is fired, thus producing the multilayer body 2. The firing temperature is preferably about 900 °C or more and about 1400 °C or less, for example, depending on the materials of the dielectric and the inner electrode layer 15. Moreover, the corners and ridge portions of the multilayer body may be rounded by, for example, barrel polishing.

Next, when a baked layer is provided as the base electrode layer 31, a conductive paste for the outer electrode 3 is applied to both end surfaces of the multilayer body 2 and is then baked, so that the baked layer of the outer electrode 3 is formed. The baking temperature is preferably about 700 °C or more and about 900 °C or less, for example. Plating is performed on a surface of the baked layer where necessary.

When a conductive resin layer is provided as the base electrode layer 31, the conductive resin layer can be formed by the following method. The conductive resin layer may be formed on a surface of the baked layer, or the conductive resin layer alone may be directly formed on the multilayer body 2 without the baked layer formed. In the method of forming a conductive resin layer, the conductive resin layer is formed by applying a conductive resin paste including a thermosetting resin and a metal component onto the baked layer or the multilayer body 2, subjecting the conductive resin paste to heat treatment at a temperature of about 250 °C to about 550 °C or more, for example, and thermally curing the resin. An N2 atmosphere is preferably provided as an atmosphere for the heat treatment at this time. In order to prevent scattering of the resin and oxidation of various metal components, a concentration of oxygen is preferably reduced to about 100 ppm or less, for example.

When a thin film layer is provided as the base electrode layer 31, the base electrode layer 31 can be formed by a thin film formation method such as sputtering or vapor deposition. The base electrode layer 31 formed of a thin film layer is a layer having a thickness of about 1μm or less, for example, in which metal particles are deposited.

The plating layer 32 may be provided on an exposed portion of the inner electrode layer 15 of the multilayer body 2, without the base electrode layer 31 provided. In this case, the plating layer 32 can be formed by the following non-limiting example method.

A plating treatment is performed on the first end surface CA and the second end surface CB of the multilayer body 2 to form a lower layer plating layer on an exposed portion of the inner electrode layer 15. The plating treatment may be electrolytic plating or electroless plating, but electroless plating would require a pretreatment with a catalyst or the like to increase the rate of plating deposition and thus involves complication of the process. Therefore, electrolytic plating is typically preferred. Barrel plating is preferably used as a plating technique. In addition, an upper layer plating electrode formed on a surface of the lower layer plating electrode may be formed in the same manner where necessary.

Thereafter, the plating layer 32 is formed on a surface of the base electrode layer 31, a surface of the conductive resin layer, or a surface of the lower layer plating layer. In the present example embodiment, an Ni plating layer and an Sn plating layer are formed, as the plating layer 32, on the baked layer. The Ni plating layer and the Sn plating layer are sequentially formed by, for example, barrel plating. In this manner, the multilayer ceramic capacitor 1 is manufactured.

The multilayer ceramic capacitor 1 manufactured by the above-described manufacturing method is mounted on the mounting substrate 101 by the following procedures.

First, the first land portion 102A and the second land portion 102B are formed on the mounting substrate 101. At this time, the distance between lands g2 is approximated to the distance between outer electrodes g1.

When the distance between lands g2 between the first land portion 102A and the second land portion 102B formed on the mounting substrate 101 is determined in advance, at the time of manufacturing the above-described multilayer ceramic capacitor 1, the distance between outer electrodes g1 may be approximated to the distance between lands g2.

Here, for example, the distance between outer electrodes g1 and the distance between lands g2 approximating each other in the present example embodiment means that about −0.44≤(g1-g2)/g2≤about 0.72 is satisfied. For example, when g2=about 0.5 mm, the distance between outer electrodes g1 and the distance between lands g2 approximating each other means that about −22 μm ≤(g1-g2)≤about 36 μm is satisfied.

In other words, the end of the mounting surface-side folded portion 351, of the first outer electrode 3A, on the second outer electrode 3B side in the length direction L and the end of the first land portion 102A on the second land portion 102B side in the length direction L are located at approximately the same position in the length direction L. In addition, the end of the mounting surface-side folded portion 351, of the second outer electrode 3B, on the first outer electrode 3A side in the length direction L and the end of the second land portion 102B on the first land portion 102A side in the length direction L are located at approximately the same position in the length direction L.

Next, the solder 103 is applied onto the land portions 102, and the multilayer ceramic capacitor 1 manufactured as described above is mounted on the land portions 102 through the solder 103.

At this time, the amount of the solder 103 is adjusted such that a distance t between the mounting-side main surface AB and the land portions 102 in the stacking direction T is adjusted. As a result, after a subsequent reflow treatment, the angle α (see FIG. 2) on an acute angle side of angles defined by a straight line drawn from an end, of the mounting surface-side folded portion 351 of one of the outer electrodes 3, on a side of another one of the outer electrodes 3 to an end of one of the land portions 102, on a side of another one of the land portions 102, and the mounting-side main surface AB satisfies about 31°≤α≤about 90°, for example.

Then, the multilayer ceramic capacitor 1 is passed through a reflow furnace and heated, and thus reflow soldering is performed. As a result, the melted solder adheres to the outer electrodes 3 so as to cover the outer electrodes 3. In this state, the solder 103 is cooled, the outer electrodes 3 of the multilayer ceramic capacitor 1 are soldered to the land portions 102 with the solder 103, and mounting of the multilayer ceramic capacitor 1 to the mounting substrate 101 is completed.

The above-described processes complete the mounting structure 100, in which the angle α on the acute angle side of the angles defined by a straight line drawn from an end, of the mounting surface-side folded portion 351 of one of the outer electrodes 3, on a side of another one of the outer electrodes 3 to an end of one of the land portions 102, on a side of another one of the land portions 102, and the mounting-side main surface AB satisfies about 31°≤α≤about 90°, for example.

In order to verify crack resistance effects of the mounting structure 100 of the present example embodiment, an example of a mounting structure for verification was manufactured as follows.

First, solder pastes were applied onto land portions (the distance between lands g2 =about 0.5 mm) of a test mounting substrate MCPCJM 0729B (substrate land: JEITA, substrate thickness: about 1.6 mm, wiring: about 1.0 mm). The amounts of the solder pastes were adjusted such that the distance t between the mounting-side main surface AB and the land portions 102 in the stacking direction T was about 0.0217 mm.

Then, the multilayer ceramic capacitor 1 was disposed on the solder pastes, and was passed through a reflow furnace and heated so as to be reflow-soldered. As a result, the melted solder adhered to the outer electrodes 3 so as to cover the outer electrodes 3. In this state, the solder 103 was cooled, and thus the outer electrodes 3 of the multilayer ceramic capacitor 1 were soldered to the land portions 102. In this manner, the multilayer ceramic capacitor 1 was mounted on the mounting substrate 101, and thus an example of the mounting structure of an electronic component was manufactured.

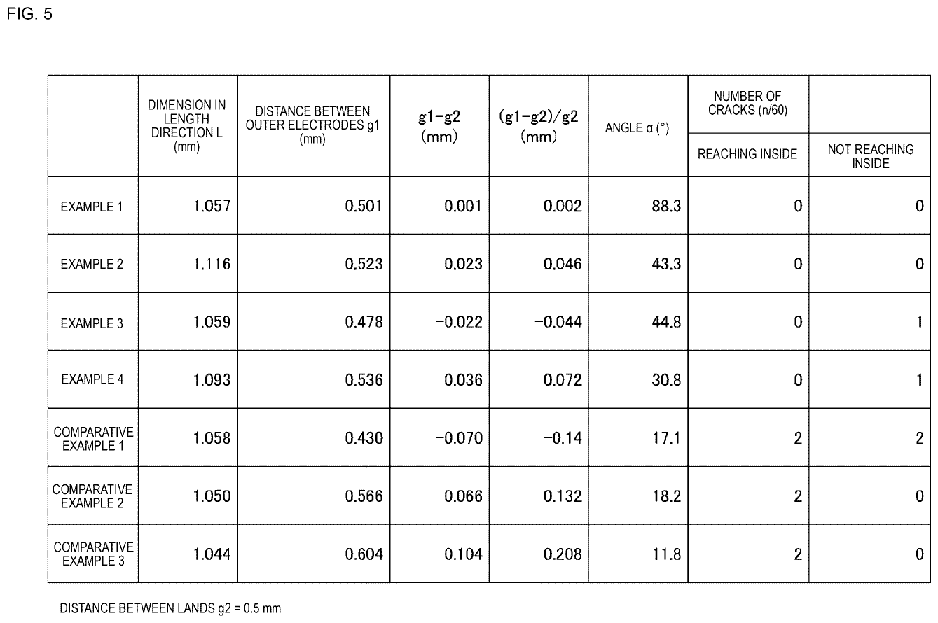

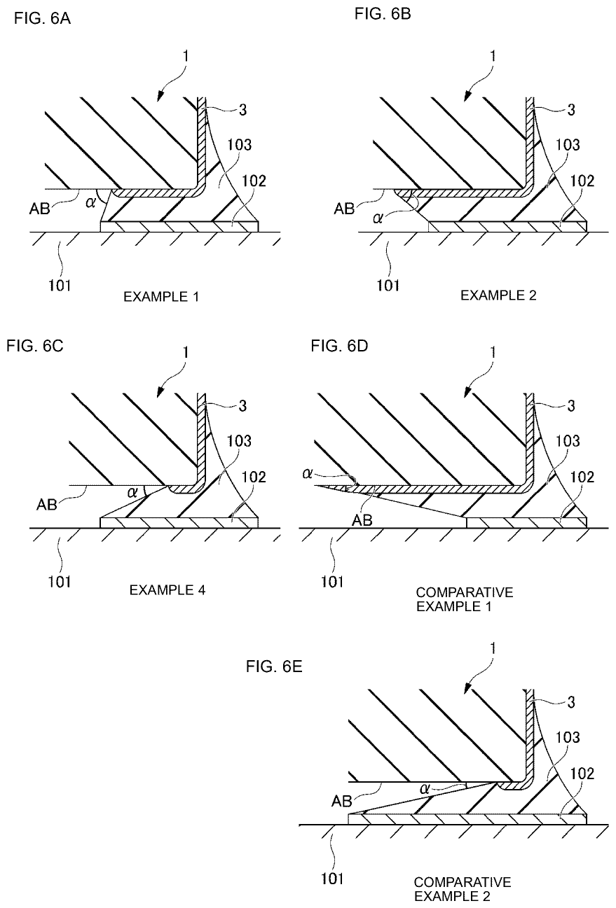

The manufactured mounting structure 100 is the mounting structures 100 of four examples and mounting structures of three comparative examples illustrated in the table of FIG. 5. FIGS. 6A to 6E illustrate portions of a region S, surrounded by a dotted line in FIG. 2, FIG. 6A illustrates a state of Example 1, FIG. 6B illustrates a state of Example 2, and FIG. 6C illustrates a state of Example 4. FIG. 6D illustrates Comparative Example 1, and FIG. 6E illustrates Comparative Example 2.

The distance between outer electrodes g1 of each of the mounting structures 100 of the four examples and the mounting structures of the three comparative examples was measured using Image Measure (IM-6140). In the measuring method, first, IM-6140 captured an appearance image of one multilayer ceramic capacitor 1. The narrowest distances between the outer electrodes 3 were measured from ten appearance images, and the average value calculated from those distances was set to be the distance between outer electrodes g1. The distance between lands g2 is about 0.5 mm in the present example embodiment, but may be measured in the same manner as the distance between outer electrodes g1.

In Example 1, g1 is about 0.501 mm, g1-g2 is about 0.001 mm, (−g2)/g2 is about 0.002 mm, and the angle α is about 88.3°.

In Example 2, g1 is about 0.523 mm, g1-g2 is about 0.023 mm, (g1-g2)/g2 is about 0.046 mm, and the angle α is about 43.3°.

In Example 3, g1 is about 0.478 mm, g1-g2 is about −0.022 mm, (g1-g2)/g2 is about −0.044 mm, and the angle α is about 44.8°.

In Example 4, g1 is about 0.536 mm, g1- g2 is about 0.036 mm, (g1-g2)/g2 is about 0.072 mm, and the angle α is about 30.8°.

That is, in Examples 1, 2, 3, and 4, about −0.44≤(g1-g2)/g2≤about 0.72 is satisfied. When g2=about 0.5 mm, about −22 μm≤g1-g2≤about 36 μm is satisfied, and thus g1 and g2 approximate each other. In addition, the angle α satisfies about 31°≤α≤about 90°.

In Comparative Example 1, g1 is 0.430 mm, g1-g2 is −0.070 mm, (g1-g2)/g2 is −0.14 mm, and the angle α is 17.1°.

In Comparative Example 2, g1 is 0.566 mm, g1-g2 is 0.066 mm, (g1-g2)/g2 is 0.132 mm, and the angle α is 18.2°.

In Comparative Example 3, g1 is 0.604 mm, g1-g2 is 0.104 mm, (g1-g2)/g2 is 0.208 mm, and the angle α is 11.8°.

That is, in Comparative Examples 1, 2, and 3, the distance from an end of a folded portion provided on a mounting-side main surface of an outer electrode to an end of a mounting land is large, and the angle α is small, which are outside the scope of example embodiments of the present invention.

Then, substrate bending resistance tests were performed on the mounting structures 100 of the four examples and the mounting structures of the three comparative examples. The test conditions were as follows: flexure amount: 2 mm, holding time: 60 seconds, pressing jig: R1, substrate land: JEITA, substrate thickness: 1.6 mm, wiring: 1.0 mm, metal mask: 36/150 μm. FIG. 5 illustrates the results of the substrate bending resistance tests performed with respect to Examples 1, 2, 3, and 4, and Comparative Example 1, 2, and 3.

In Examples 1 and 2, which are within the scope of example embodiments of the present invention, the number of cracks that have reached the inside of the multilayer body 2 was zero, and the number of cracks that have occurred in the outer layer portion 12 but have not reached the inside of the multilayer body 2 was zero. In Examples 3 and 4, although the number of cracks that have occurred in the outer layer portion 12 but have not reached the inside of the multilayer body 2 was one, the number of cracks that have reached the inside of the multilayer body 2 was zero.

In Comparative Example 1, which is outside the scope of example embodiments of the present invention, the number of cracks that have occurred in the outer layer portion 12 but have not reached the inside of the multilayer body 2 was two, and the number of cracks that have reached the inside of the multilayer body 2 was also two. In Comparative Examples 2 and 3, although the number of cracks that have occurred in the outer layer portion 12 but have not reached the inside of the multilayer body 2 was zero, the number of cracks that have reached the inside of the multilayer body 2 was two.

From the verification results described above, improvement of the crack resistance has been confirmed in Examples 1, 2, 3, and 4, which are within the scope of example embodiments of the present invention, compared to Comparative Examples 1, 2, and 3.

The crack resistance in the mounting structures 100 of the example embodiments is considered to be improved for the following reasons. Assuming that a straight line drawn from an end of the mounting surface-side folded portion 351 of the outer electrode 3 to an end of the land portion 102 is substantially equal to an outline of an outer surface of each solder 103, the angle α is an angle on the acute angle side formed by the outline of the outer surface of the solder 103 and the mounting-side main surface AB. It is considered that, as the angle α decreases, a stress is likely to concentrate in the end of the mounting surface-side folded portion 351 when the mounting structure 100 is bent. In the comparative examples, the angle α is small. Therefore, it is considered that a stress concentrates in the end of the mounting surface-side folded portion 351, and a crack easily occurs. On the other hand, in the examples, the angle α on the angle side is large. Therefore, it is considered that a stress does not easily concentrate in the end of the mounting surface-side folded portion 351, and a crack does not easily occur.

Example embodiments of the present invention have been described above, but the present invention is not limited to the example embodiments, and various changes and modifications can be made thereto.

While example embodiments of the present invention have been described above, it is to be understood that variations and modifications will be apparent to those skilled in the art without departing from the scope and spirit of the present invention. The scope of example embodiments of the present invention, therefore, is to be determined solely by the following claims.

What is claimed is:

1. A mounting structure of an electronic component comprising:
an electronic component including:
a multilayer body including:
a mounting-side main surface and a non-mounting-side main surface opposite to each other in a stacking direction;
two side surfaces opposite to each other in a width direction intersecting with the stacking direction; and
a first end surface and a second end surface opposite to each other in a length direction intersecting with the stacking direction and the width direction;
a first outer electrode provided on the first end surface and including a mounting surface-side folded portion that extends to the mounting-side main surface; and
a second outer electrode provided on the second end surface and including a mounting surface-side folded portion that extends to the mounting-side main surface; and
a mounting substrate including:
a first land to which the first outer electrode is bonded through solder; and
a second land to which the second outer electrode is bonded through solder; wherein
when a distance between the first and second outer electrodes g1 is a distance in the length direction between an end of the mounting surface-side folded portion of the first outer electrode on a second outer electrode side in the length direction and an end of the mounting surface-side folded portion of the second outer electrode on a first outer electrode side in the length direction; and
a distance between the first and second lands g2 is a distance in the length direction between an end of the first land on a second land side in the length direction and an end of the second land on a first land side in the length direction;
the distance g1 and the distance g2 approximate each other.

2. The mounting structure of an electronic component according to claim 1, wherein about −0.44≤(g1-g2)/g2≤about 0.72 is satisfied.

3. The mounting structure of an electronic component according to claim 1, wherein about 2 2μm≤g1-g2≤about 36 μm is satisfied.

4. The mounting structure of an electronic component according to claim 1, wherein the electronic component is a multilayer ceramic capacitor.

5. The mounting structure of an electronic component according to claim 1, wherein the electronic component has a dimension in the length direction of about 0.8 mm or more and about 1.2 mm or less, a dimension in the stacking direction of about 0.3 mm or more and about 0.7 mm or less, and a dimension in the width direction of about 0.3 mm or more and about 0.7 mm or less.

6. The mounting structure of an electronic component according to claim 1, wherein the multilayer body has a dimension in the length direction of about 0.7 mm or more and about 1.2 mm or less, a dimension in the width direction of about 0.2 mm or more and about 0.7 mm or less, and a dimension in the stacking direction of about 0.2 mm or more and about 0.7 mm or less.

7. The mounting structure of an electronic component according to claim 3, wherein g2 is about 0.5 mm.

8. The mounting structure of an electronic component according to claim 1, wherein g1 and g2 are each about 0.5 mm.

9. The mounting structure of an electronic component according to claim 1, wherein
an end of the mounting surface-side folded portion of the first outer electrode on a second outer electrode side in the length direction and an end of the first land on a second land side in the length direction are located at approximately a same position in the length direction; and
an end of the mounting surface-side folded portion of the second outer electrode on a first outer electrode side in the length direction and an end of the second land on a first land side in the length direction are located at approximately a same position in the length direction.

10. The mounting structure of an electronic component according to claim 1, wherein an angle α on an acute angle side of angles defined by a straight line drawn from an end of the mounting surface-side folded portion of one of the outer electrodes on a side of another one of the outer electrodes to an end of one of the lands on a side of another one of the lands and the mounting-side main surface satisfies about 31°≤α≤about 90°.

11. The mounting structure of an electronic component according to claim 10, wherein the angle α is approximately 90°.

12. A mounting structure of an electronic component comprising:
an electronic component including:
a multilayer body including:
a mounting-side main surface and a non-mounting-side main surface opposite to each other in a stacking direction;
two side surfaces opposite to each other in a width direction intersecting with the stacking direction; and
a first end surface and a second end surface opposite to each other in a length direction intersecting with the stacking direction and the width direction;
a first outer electrode provided on the first end surface and including a mounting surface-side folded portion that extends to the mounting-side main surface; and
a second outer electrode provided on the second end surface and including a mounting surface-side folded portion that extends to the mounting-side main surface; and
a mounting substrate including:
a first land to which the first outer electrode is bonded through solder; and
a second land to which the second outer electrode is bonded through solder; wherein
an end of the mounting surface-side folded portion of the first outer electrode on a second outer electrode side in the length direction and an end of the first land on a second land side in the length direction are located at approximately a same position in the length direction; and
an end of the mounting surface-side folded portion of the second outer electrode on a first outer electrode side in the length direction and an end of the second land on a first land side in the length direction are located at approximately a same position in the length direction.

13. The mounting structure of an electronic component according to claim 12, wherein the electronic component is a multilayer ceramic capacitor.

14. The mounting structure of an electronic component according to claim 12, wherein the electronic component has a dimension in the length direction of about 0.8 mm or more and about 1.2 mm or less, a dimension in the stacking direction of about 0.3 mm or more and about 0.7 mm or less, and a dimension in the width direction of about 0.3 mm or more and about 0.7 mm or less.

15. The mounting structure of an electronic component according to claim 12, wherein the multilayer body has a dimension in the length direction of about 0.7 mm or more and about 1.2 mm or less, a dimension in the width direction of about 0.2 mm or more and about 0.7 mm or less, and a dimension in the stacking direction of about 0.2 mm or more and about 0.7 mm or less.

16. A mounting structure of an electronic component comprising:
an electronic component including:
a multilayer body including:
a mounting-side main surface and a non-mounting-side main surface opposite to each other in a stacking direction;
two side surfaces opposite to each other in a width direction intersecting with the stacking direction; and
two end surfaces opposite to each other in a length direction intersecting with the stacking direction and the width direction; and
outer electrodes provided on the two end surfaces and including mounting surface-side folded portions that extend to the mounting-side main surface; and
a mounting substrate including:
lands to which the outer electrodes are bonded through solder; wherein
an angle α on an acute angle side of angles defined by a straight line drawn from an end of the mounting surface-side folded portion of one of the outer electrodes on a side of another one of the outer electrodes to an end of one of the lands on a side of another one of the lands and the mounting-side main surface satisfies about 31°≤α≤about 90°.

17. The mounting structure of an electronic component according to claim 16, wherein the angle α is approximately 90°.

18. The mounting structure of an electronic component according to claim 16, wherein the electronic component is a multilayer ceramic capacitor.

19. The mounting structure of an electronic component according to claim 16, wherein the electronic component has a dimension in the length direction of about 0.8 mm or more and about 1.2 mm or less, a dimension in the stacking direction of about 0.3 mm or more and about 0.7 mm or less, and a dimension in the width direction of about 0.3 mm or more and about 0.7 mm or less.

20. The mounting structure of an electronic component according to claim 16, wherein the multilayer body has a dimension in the length direction of about 0.7 mm or more and about 1.2 mm or less, a dimension in the width direction of about 0.2 mm or more and about 0.7 mm or less, and a dimension in the stacking direction of about 0.2 mm or more and about 0.7 mm or less.
